(19) United States
(12) Patent Application Publication
(10) Pub. No.: US 2009/0303605 A1
(43) Pub. Date: Dec. 10, 2009

(54) TRANSPARENT MULTILAYER FILM, METHOD OF PRODUCING THE SAME, AND LIQUID LENS

(75) Inventor: Shina Kirita, Tokyo (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: SONY CORPORATION, TOKYO (JP)

(21) Appl. No.: 12/301,595

(22) PCT Filed: May 25, 2007
(86) PCT No.: PCT/JP2007/060723

§ 371 Date: Jul. 2, 2009

(30) Foreign Application Priority Data
May 26, 2006 (JP) 2006-146189

(51) Int. Cl. G02B 3/14; C23C 14/34; B32B 7/02; G02B 1/06

(52) U.S. Cl. 359/666; 204/192.15; 428/336; 428/697; 428/428

(57) ABSTRACT

A method of producing a transparent multilayer film which enables to easily deposit a transparent multilayer film without changing a target material is provided, and a transparent multilayer film formed by the method of producing a transparent multilayer film and a liquid lens including the transparent multilayer film are provided. A transparent conductive film is deposited on a base by sputtering a target 3 made of ZnO containing any of Al₂O₃, Ga₂O₃, and SiO₂ using a sputtering gas without a reactive gas being present or in the presence of a reactive gas, and a transparent insulating film is then deposited on the transparent conductive film by sputtering the target using a sputtering gas in the presence of a reactive gas, thereby forming a transparent multilayer film.

### TECHNICAL FIELD

The present invention relates to a transparent multilayer film, a method of producing the same, and a liquid lens including the transparent multilayer film.

### BACKGROUND ART

Hitherto, techniques that can be used to realize variable focus without mechanically moving a lens have been proposed. Among them, a liquid lens utilizing an electrowetting effect has attracted attention (for example, see PCT Publication No. 99/18456, Japanese Unexamined Patent Application Publication No. 2002-162506, and Bruno Berge, No mechanical components, The possibility of liquid lenses, which will be mass-produced soon, Nikkei Electronics, Nikkei Inc., Oct. 24, 2005, pp. 129-135).

Such a liquid lens has a structure composed of, for example, from the top, base 101/electrode 102/aqueous solution 103/oil 104/insulating film 105/electrode 106/base 107. By applying a voltage between the electrode 102 and the electrode 106 to change the shape of an interface between the aqueous solution 103 and the oil 104, driving for changing the focus is performed.

Here, in the liquid lens, the structure of insulating film 105/electrode 106/base 107 is prepared by separate processes, namely, by depositing, as the electrode 106, a metal film or a transparent conductive film on the base 107 by a sputtering method, and then depositing the insulating film 105 having a film thickness of several micrometers on the electrode 106 by an evaporation method, and thus, the production of the multilayer film is complicated.

In addition, in conventional liquid lenses, it is necessary to apply a voltage of several tens of volts or more in order to perform driving for changing the focus. Therefore, in the case where such liquid lenses are used in various types of optical devices, in particular, in the case where a large number of small liquid lenses are used, the application thereof is difficult, and a decrease in the voltage to be applied has been desired.

The present invention has been made in view of the problems in the related art described above. It is an object of the present invention to provide a method of producing a transparent multilayer film which enables to easily deposit a transparent multilayer film without changing a target material and to provide a transparent multilayer film formed by the method of producing a transparent multilayer film and a liquid lens including the transparent multilayer film.

### DISCLOSURE OF INVENTION

An invention of Claim 1 provided in order to solve the above problems is a method of producing a transparent multilayer film characterized in that a transparent conductive film is deposited on a base by sputtering a target made of ZnO containing any of Al₂O₃, Ga₂O₃, and SiO₂ using a sputtering gas without a reactive gas being present or in the presence of a reactive gas, and a transparent insulating film is then deposited on the transparent conductive film by sputtering the target using a sputtering gas in the presence of a reactive gas, thereby forming a transparent multilayer film.

In addition, an invention of Claim 2 provided in order to solve the above problems is a method of producing a transparent multilayer film characterized in that, in the invention of claim 1, the content of any of Al₂O₃, Ga₂O₃, and SiO₂ of the target is 10 weight percent or less.

In addition, an invention of Claim 3 provided in order to solve the above problems is a method of producing a transparent multilayer film characterized in that, in the invention of Claim 1, the film thickness of the transparent insulating film is 1 μm or less.

In addition, an invention of Claim 4 provided in order to solve the above problems is a method of producing a transparent multilayer film characterized in that, in the invention of Claim 1, a resistance value of the transparent insulating film is adjusted by changing a flow-rate ratio of the reactive gas to the sputtering gas.

An invention of Claim 5 provided in order to solve the above problems is a transparent multilayer film characterized in that a transparent conductive film and a transparent insulating film are sequentially laminated on a base by the method of producing a transparent multilayer film according to any one of Claims 1 to 4.

An invention of Claim 6 provided in order to solve the above problems is a liquid lens characterized in that an oil and an aqueous solution are sealed by the transparent multilayer film according to claim 5 and a member including an electrode so that the transparent insulating film is located inside, and, by applying a voltage between the electrode and the transparent conductive film, the shape of an interface between the aqueous solution and the oil on the transparent insulating film is changed.

According to the method of producing a transparent multilayer film of the present invention, the transparent multilayer film can be easily deposited using a single target without changing the target material in one sputtering deposition step.

According to the transparent multilayer film of the present invention, a transparent multilayer film suitable for a liquid lens can be provided.

According to a liquid lens of the present invention, a transparent multilayer film having a high dielectric constant and a small film thickness is provided, and thus the liquid lens can be driven at a low voltage.

### BRIEF DESCRIPTION OF DRAWINGS

FIG. 1 is a schematic diagram showing the structure of a sputtering apparatus used when a method of producing a transparent multilayer film according to the present invention is carried out.

FIG. 2 is a cross-sectional view showing the structure of a transparent multilayer film according to the present invention.

FIG. 3 is a cross-sectional view showing the structure of a liquid lens according to the present invention.

FIG. 4 is a schematic view showing a state of tensions of interfaces in the case where no voltage is applied between a transparent conductive film and an electrode.

FIG. 5 is a schematic view showing a state of tensions of interfaces in the case where a voltage is applied between the transparent conductive film and the electrode.

FIG. 6 is a cross-sectional view showing the structure of a conventional transparent multilayer film.

FIG. 7 is a drawing showing the relationship between a reactive gas flow-rate ratio and a specific resistance of Example 1.

FIG. 8 is a drawing showing the relationship between a reactive gas flow-rate ratio and a specific resistance of Example 2.

FIG. 9 is a drawing showing a connecting structure when withstand voltage measurement is performed using a transparent multilayer film.

FIG. 10 is a drawing showing withstand voltage measurement results of a transparent multilayer film.

FIG. 11 is a drawing showing withstand voltage measurement results of a transparent multilayer film.

### BEST MODES FOR CARRYING OUT THE INVENTION

A method of producing a transparent multilayer film according to the present invention will now be described.

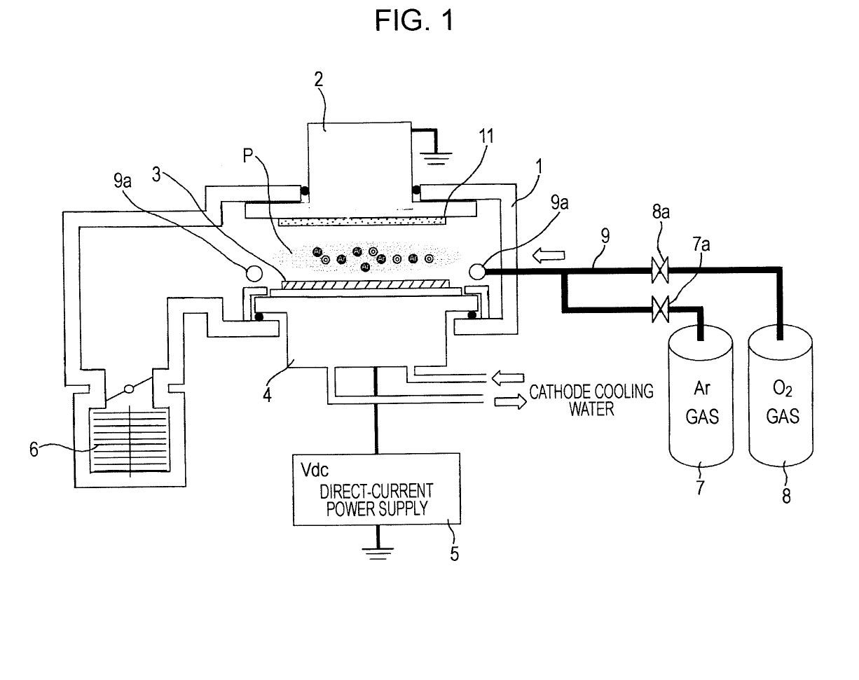

FIG. 1 is a schematic diagram showing the structure of a sputtering apparatus used when the method of producing a transparent multilayer film according to the present invention is carried out.

As shown in FIG. 1, the sputtering apparatus is a DC sputtering apparatus, and a substrate holder 2 that holds a substrate 11 and a target holder 4 that holds a target 3 are disposed in a chamber 1 so as to face each other so that a voltage is applied between the substrate 11 and the target 3. Specifically, the substrate 11 is grounded to a ground via the substrate holder 2, the target 3 is connected to a direct-current power supply 5 via the target holder 4, and a predetermined minus voltage relative to the earth electric potential of the substrate 11 is applied from the direct-current power supply 5 to the target 3.

In addition, the sputtering apparatus includes an evacuation pump 6 serving as an exhaust system in the chamber 1. Furthermore, the sputtering apparatus includes, as a gas supply system, an Ar gas cylinder 7, an O₂ gas cylinder 8, and gas piping 9 in which gases supplied from the gas cylinders 7 and 8 are mixed in midstream and which leads the mixed gas into the chamber 1. The flow-rate ratio of the gases and the flow rate of the mixed gas are controlled by an Ar gas flow rate controller 7a and an O₂ gas flow rate controller 8a, both of which are provided in the gas piping 9, and the mixed gas is introduced from a process gas inlet 9a into the chamber 1.

When a transparent multilayer film is deposited on the substrate 11 using this sputtering apparatus, the process is performed in accordance with the following procedure.

(S11) The substrate 11 is set on the substrate holder 2.

Here, the substrate 11 is a transparent glass substrate or a transparent resin substrate made of any of polycarbonate (PC), polyethylene terephthalate (PET), polyethylene naphthalate (PEN), polyethersulfone (PES), and polyolefin (PO), the substrate having a clean surface.

(S12) The target 3 is set on the target holder 4.

Here, the target 3 is a target made of ZnO containing any of Al₂O₃, Ga₂O₃, and SiO₂ (that is, any of an AZO target, a GZO target, and an SZO target), and the content of any of Al₂O₃, Ga₂O₃, and SiO₂ in the target 3 is preferably 10 weight percent or less, for example, preferably in the range of 1.0 to 10.0 weight percent.

(S13) The chamber 1 is evacuated using the evacuation pump 6 to be in a vacuum state.

(S14) Subsequently, a mixed gas containing predetermined amounts of gases supplied from the Ar gas cylinder 7 and the O₂ gas cylinder 8 is introduced from the process gas inlet 9a into the chamber 1, while continuing the evacuation, so that the atmosphere in the chamber 1 is at a constant pressure (for example, 0.1 to 1.0 Pa). Here, the ratio of the flow rates (sccm) of the mixed gas (reactive gas flow-rate ratio (O₂/Ar)) is adjusted such that a transparent film to be deposited has a predetermined resistance value or less to exhibit electrical conductivity (for example, 0.2% in the case of an AZO target). Alternatively, only Ar gas may be introduced into the chamber 1 without introducing O₂ gas.

(S15) Subsequently, a DC voltage is applied between the target 3 and the substrate 11 from the direct-current power supply 5 to generate a glow discharge in the atmosphere gas (O₂+Ar, or Ar), thereby forming a plasma state P.

(S16) Electric power (for example, 0.1 to 7.8 W/cm²) is supplied from the direct-current power supply 5 to start sputtering, and a transparent conductive film 12 based on the target composition is formed on the substrate 11 (Once, a deposition is finished).

(S17) Subsequently, a mixed gas containing predetermined amounts of gases supplied from the Ar gas cylinder 7 and the O₂ gas cylinder 8 is introduced from the process gas inlet 9a into the chamber 1, while continuing the evacuation, so that the atmosphere in the chamber 1 is at a constant pressure (for example, 0.1 to 1.0 Pa). Here, the ratio of the flow rates (sccm) of the mixed gas (reactive gas flow-rate ratio (O₂/Ar)) is adjusted such that a transparent film to be deposited has a predetermined resistance value to exhibit an insulating property. That is, by excessively incorporating oxygen to the film by adjusting the reactive gas flow-rate ratio and the electric power supplied, the insulating property is ensured. It is sufficient that the reactive gas flow-rate ratio is 2% or less, and for example, 1.3% in the case of an AZO target.

(S18) Subsequently, a DC voltage is applied between the target 3 and the substrate 11 from the direct-current power supply 5 to generate a glow discharge in the atmosphere gas (O₂+Ar), thereby forming a plasma state P.

(S19) Electric power (for example, 0.1 to 7.8 W/cm²) is supplied from the direct-current power supply 5 to start sputtering, and a transparent insulating film 13 based on the target composition is formed on the transparent conductive film 12 to complete a transparent multilayer film.

Alternatively, as another method of producing a transparent multilayer film, after the start of the deposition in step S16 described above, sputtering deposition may be performed while gradually increasing the reactive gas flow-rate ratio (O₂/Ar) to form a gradient film in which the resistance value gradually changes in the film thickness direction.

In this case, an interface between the transparent conductive film and the transparent insulating film is not present, and thus the adhesiveness is improved.

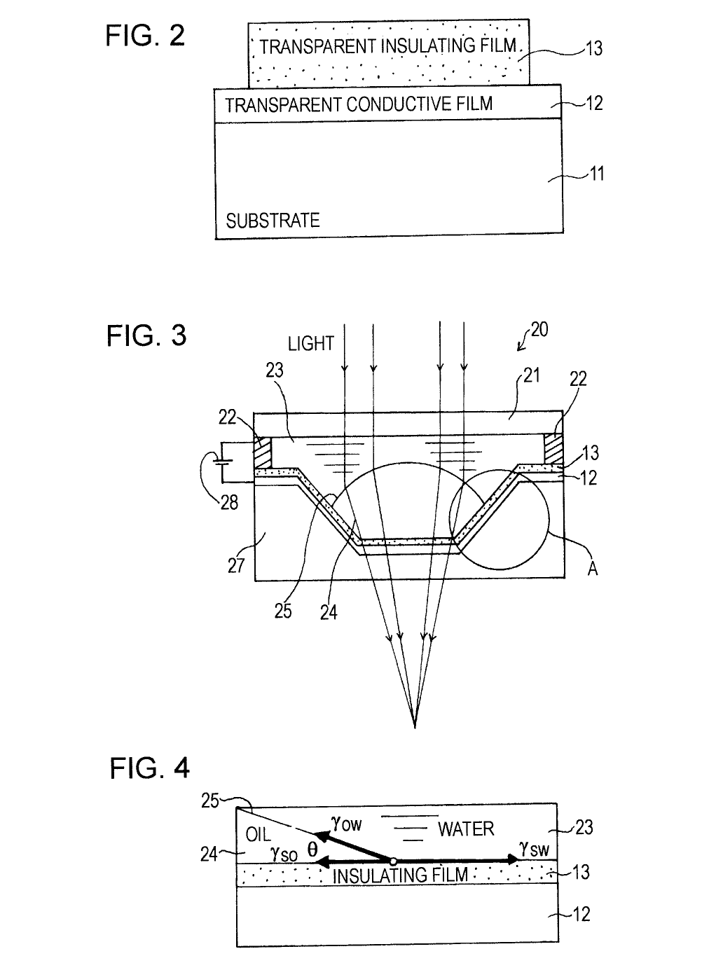

FIG. 2 shows a cross-sectional structure of the transparent multilayer film formed by the method described above.

The transparent multilayer film of the present invention is an optical film having a multilayer structure in which the transparent conductive film 12 and the transparent insulating film 13 are provided on the substrate 11.

As described above, the transparent conductive film 12 is a transparent film based on the composition of the target 3, and for example, the specific resistance is in the range of 1.0×10⁻³ to 1.0×10⁻² (Ω·cm), and the average absorption ratio of transmitted light having a wavelength in the range of 380 to 780 nm is 3% or less. In addition, the film thickness of the transparent conductive film 12 is in the range of 20 to 200 nm.

As described above, the transparent insulating film 13 is a transparent film based on the composition of the target 3 which has been used for forming the transparent conductive film 12, and for example, the specific resistance is in the range of 1.0×10⁺² to 1.0×10⁺⁷ (Ω·cm), and the average absorption ratio of transmitted light having a wavelength in the range of 380 to 780 nm is 3% or less. In addition, the film thickness of the transparent insulating film 13 is 1 μm or less, and preferably in the range of 200 to 600 nm.

Next, a liquid lens of the present invention will be described.

FIG. 3 is a cross-sectional view showing the structure of a liquid lens of the present invention. In FIG. 3, the optical axis of a liquid lens 20 extends in the vertical direction, and light is incident on a base 21 of the liquid lens 20 from above in the figure and emitted from a base 27.

The liquid lens 20 of the present invention has a structure in which an oil 24 and an aqueous solution 23 are sealed by a transparent multilayer film of the present invention (a transparent conductive film 12 and a transparent insulating film 13) provided on the transparent base 27 having a recess at the center thereof and a member including an electrode 22 (the base 21 and the electrode 22) so that the transparent insulating film 13 is located inside. By applying a voltage between the electrode 22 and the transparent conductive film 12, the shape of an interface between the aqueous solution 23 and the oil 24 on the transparent insulating film 13 is changed, and incident light is converged or diverged, and emitted.

Each of the bases 21 and 27 is a transparent glass substrate or a transparent resin substrate made of any of polycarbonate (PC), polyethylene terephthalate (PET), polyethylene naphthalate (PEN), polyethersulfone (PES), and polyolefin (PO).

In addition, the transparent conductive film 12 and the transparent insulating film 13 are formed on the base 27 by the above-described method of producing a transparent multilayer film, and the transparent insulating film 13 is in contact with the aqueous solution 23 and the oil 24. Furthermore, the electrode 22 is provided between the base 21 and the transparent insulating film 13 so as to seal the aqueous solution 23 and the oil 24. In addition, a power supply 28 is connected to the transparent conductive film 12 and the electrode 22 so that a predetermined voltage is applied between the transparent conductive film 12 and the electrode 22.

Liquids which have the same specific gravity and different refractive indices and which are not mixed with each other (which are insoluble with each other) are selected as the aqueous solution 23 and the oil 24. For example, the aqueous solution 23 is an electrolyte solution (a liquid having electrical conductivity or polarity) which is prepared by mixing water and ethyl alcohol in a predetermined ratio, and further adding a predetermined amount of NaCl and which has a specific gravity of 1.06 and a refractive index of 1.38 at room temperature, and the oil 24 is a colorless and transparent silicone oil having a specific gravity of 1.06 and a refractive index of 1.49 at room temperature.

When the aqueous solution 23 and the oil 24 are sealed, first, the oil 24 is dripped onto the transparent insulating film 13 in the recess of the base 27, and the remaining space of a sealing region is then filled with the aqueous solution 23. Thereby, the aqueous solution 23 and the oil 24 are each independently present without being mixed with each other to form an interface 25.

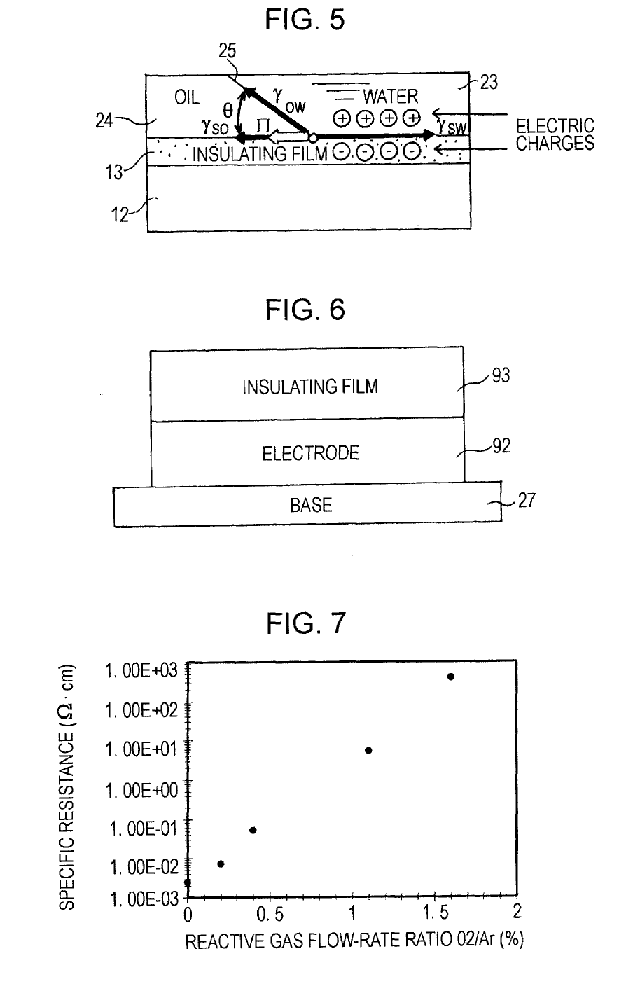

FIGS. 4 and 5 show a driving principle of the liquid lens 20. FIG. 4 shows a state of tensions of respective interfaces of transparent insulating film 13/oil 24/aqueous solution 23 in the case where no voltage is applied between the transparent conductive film 12 and the electrode 22, and FIG. 5 shows the state in the case where a voltage is applied between the transparent conductive film 12 and the electrode 22.

In the inside of the liquid lens 20, three interfacial tensions are generated in transparent insulating film 13/oil 24/aqueous solution 23. Namely, the three interfacial tensions are a tension (SW) between the transparent insulating film 13 and the aqueous solution 23, a tension (OW) between the oil 24 and the aqueous solution 23, and a tension (SO) between the transparent insulating film 13 and the oil 24. Herein, these tensions are represented by γ_{SW}, γ_{OW}, and γ_{SO}, respectively.

In the case where no voltage is applied between the transparent conductive film 12 and the electrode 22, the relationship represented by the following formula is satisfied between the three interfacial tensions and the angle of contact (θ) between the transparent insulating film 13 and the oil 24 from the so-called Young-Laplace equation, and the shape of the interface 25 is determined on the basis of the relationship (FIG. 4).

cos θ=(γ_{SW}−γ_{SO})/γ_{OW}

In the case where a voltage is applied between the transparent conductive film 12 and the electrode 22, the shape of the interface 25 is changed by an electrowetting effect. That is, electric charges are generated at an interface between the transparent insulating film 13 and the aqueous solution 23 by the application of the voltage. Thereby, a pressure π represented by the following formula is applied in the direction of the tension (SO) between the transparent insulating film 13 and the oil 24.

π=½(ε·ε₀/d)V²

(Here, ε represents the dielectric constant of an insulating portion, ε0 represents the vacuum dielectric constant, d represents the thickness of the insulating portion, and V represents the applied voltage.)

Accordingly, in this case, the relationship represented by the following formula is satisfied between the three interfacial tensions and the angle of contact (θ) between the transparent insulating film 13 and the oil 24. The angle of contact θ increases as compared with a case where no voltage is applied, and thus the shape of the interface 25 is changed. Furthermore, the degree of the change can be controlled by changing the voltage.

cos θ=(γ_{SW}−γ_{SO})/γ_{OW}−½(ε·ε₀/d)V² (1)

As described above, the focal length of the liquid lens 20 can be changed by changing the shape of the interface 25 between the aqueous solution 23 and the oil 24 having different refractive indices, and in addition, the focal length can be controlled by the applied voltage.

In addition, as compared with conventional liquid lenses, the liquid lens of the present invention exhibits excellent performance.

For example, in a conventional liquid lens, instead of the transparent multilayer film of the present invention, an electrode film 92 formed on a base 27 by depositing indium tin oxide (ITO) by a sputtering method or an evaporation method and an insulating film 93 formed on the electrode film 92 by evaporating parylene (manufactured by Parylene Japan Inc., parylene C or parylene N) so as to have a thickness of several micrometers are laminated (FIG. 6).

Here, when a case where an insulating film 93 made of parylene (film thickness: 2 μm, dielectric constant: 2.65) is used as a conventional liquid lens is compared with a case where a transparent insulating film 13 (film thickness: 100 nm, dielectric constant: 8.7) formed by using a target of ZnO-2 wt % Al₂O₃ is used in the liquid lens 20 of the present invention, the film thicknesses of the insulating films differ by 20 times, and the dielectric constants of the insulating films differ by 3.28 times. That is, from formula (1) above, in the liquid lens 20 of the present invention, the applied voltage can be 1/65.6 that of the conventional liquid lens. For example, if the voltage applied to the conventional liquid lens is in the range of 40 to 100 V, in the liquid lens 20 of the present invention, the applied voltage can be reduced to 4.93 to 12.35 V.

### EXAMPLES

Examples carried out in order to verify the present invention will be described below.

### Example 1

A transparent film sample was prepared using the sputtering apparatus shown in FIG. 1 under the following conditions.
Substrate 11: glass substrate
Target 3: ZnO-2 wt % Al₂O₃
Supplied electric power: 0.1 to 7.8 W/cm²
Reactive gas flow-rate ratio (O₂/Ar): 0(%) to 1.6(%)

Note that (reactive gas flow-rate ratio)=(O₂ gas flow rate)/{(O₂ gas flow rate)+(Ar gas flow rate)}×100(%).
Film thickness of transparent film: 100 nm

FIG. 7 shows the measurement results of the specific resistance of the prepared sample.

According to the results, a tendency that the specific resistance increased in proportion to the reactive gas flow-rate ratio was observed. In accordance with this result, for example, by forming the transparent conductive film 12 at a reactive gas flow-rate ratio of 0.2%, and next, forming the transparent insulating film 13 at a reactive gas flow-rate ratio of 1.3% using the same target 3, a transparent multilayer film of the present invention can be obtained.

### Example 2

A transparent film sample was prepared using the sputtering apparatus shown in FIG. 1 under the following conditions.
Substrate 11: glass substrate (area: 9 cm²)
Target 3: ZnO-2 wt % SiO₂
Supplied electric power: 100 to 400 W
Reactive gas flow-rate ratio (O₂/Ar): 0(%) to 0.5(%)
Film thickness of transparent film: 100 nm

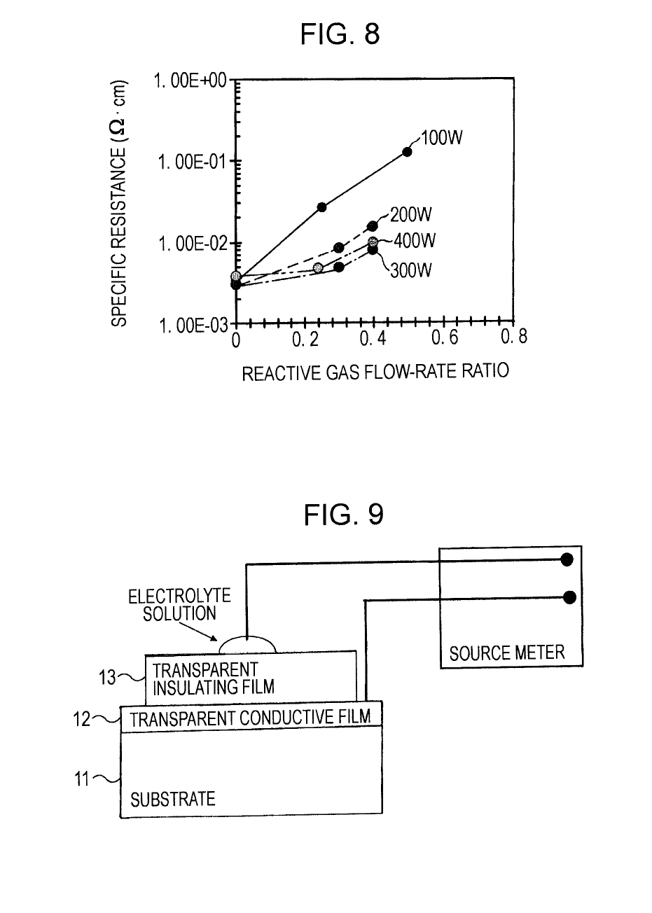

FIG. 8 shows the measurement results of the specific resistance of the prepared sample.

According to the results, a tendency that the specific resistance increased in proportion to the reactive gas flow-rate ratio was observed. Furthermore, a tendency that the specific resistance decreased in proportion to the supplied electric power was observed.

### Example 3

A transparent multilayer film sample was prepared by the method of producing a transparent multilayer film of the present invention under the following conditions. Note that a glass substrate was used as the substrate 11.

(1) Transparent conductive film 12
Target 3: ZnO-2 wt % Al₂O₃
Reactive gas flow-rate ratio (O₂/Ar): 0.2(%)
Film thickness: 100 nm
   (2) Transparent insulating film 13
Target 3: ZnO-2 wt % Al₂O₃
Reactive gas flow-rate ratio (O₂/Ar): 1.3(%)
Film thickness: 200 nm

Withstand voltage evaluation was performed using the prepared sample. Specifically, as shown in FIG. 9, the transparent multilayer film sample was connected to a source meter, and a voltage was applied to a probe that was in contact with the transparent conductive film 12 while varying the voltage in the range of 0 to 60 V, and the current value flowing at that time through a probe that was in contact with an electrolyte solution on the transparent insulating film 13 was measured.

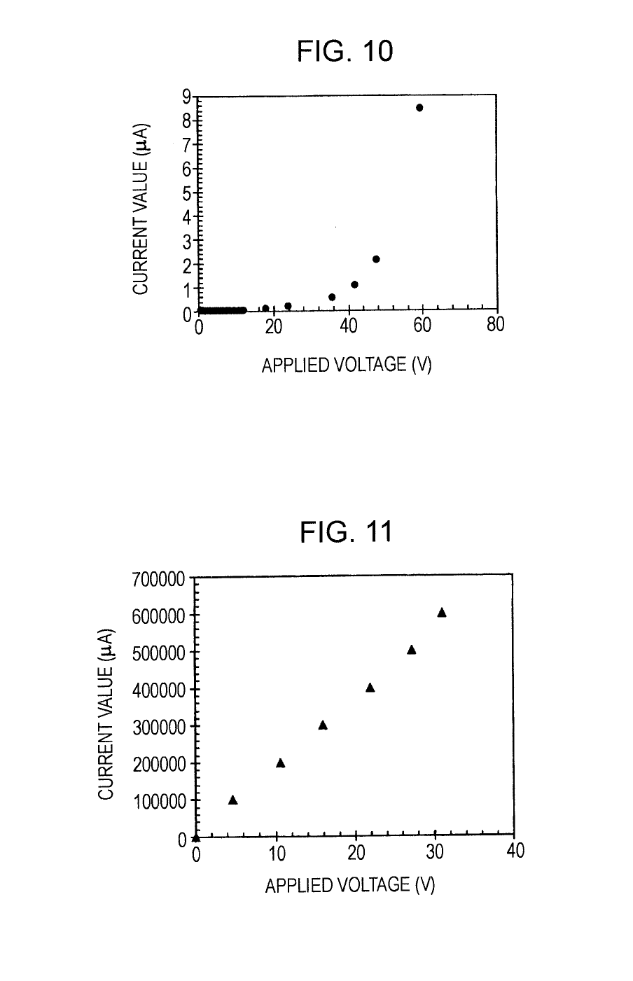

FIG. 10 shows the results. In addition, FIG. 11 shows results when a similar withstand voltage measurement was performed using a sample in which the transparent insulating film 13 in the structure of the transparent multilayer film sample was omitted and only the transparent conductive film 12 was formed.

As compared with the results (FIG. 11) of the sample in which only the transparent conductive film 12 was formed, the transparent multilayer film sample did not show an ohmic reaction, and a withstand voltage characteristic equivalent to that of a product having a conventional structure (a multilayer film including an insulating film made of parylene shown in FIG. 6) was confirmed.

Furthermore, a liquid lens including a transparent multilayer film prepared under the conditions of this Example was prepared. The focal length of the liquid lens could be variably controlled by applying a voltage.

1. A method of producing a transparent multilayer film characterized in that a transparent conductive film is deposited on a base by sputtering a target made of ZnO containing any of Al₂O₃, Ga₂O₃, and SiO₂ using a sputtering gas without a reactive gas being present or in the presence of a reactive gas, and a transparent insulating film is then deposited on the transparent conductive film by sputtering the target using a sputtering gas in the presence of a reactive gas, thereby forming a transparent multilayer film.

2. The method of producing a transparent multilayer film according to claim 1, characterized in that the content of any of Al₂O₃, Ga₂O₃, and SiO₂ of the target is 10 weight percent or less.

3. The method of producing a transparent multilayer film according to claim 1, characterized in that the film thickness of the transparent insulating film is 1 μm or less.

4. The method of producing a transparent multilayer film according to claim 1, characterized in that a resistance value of the transparent insulating film is adjusted by changing a flow-rate ratio of the reactive gas to the sputtering gas.

5. A transparent multilayer film characterized in that a transparent conductive film and a transparent insulating film are sequentially laminated on a base by the method of producing a transparent multilayer film according to any one of claims 1 to 4.

6. A liquid lens characterized in that an oil and an aqueous solution are sealed by the transparent multilayer film according to claim 5 and a member including an electrode so that the transparent insulating film is located inside, and, by applying a voltage between the electrode and the transparent conductive film, the shape of an interface between the aqueous solution and the oil on the transparent insulating film is changed.
